(19) United States
(12) Patent Application Publication
(10) Pub. No.: US 2013/0076444 A1
(43) Pub. Date: Mar. 28, 2013

(54) Amplification Circuit, Communication Device, and Transmission Device Using Amplification Circuit

(71) Applicants: Shinji Aikawa, Kirishima-shi (JP); Akira Nagayama, Kunitachi-shi (JP); Yasuhiko Fukuoka, Kizugawa-shi (JP)

(72) Inventors: Shinji Aikawa, Kirishima-shi (JP); Akira Nagayama, Kunitachi-shi (JP); Yasuhiko Fukuoka, Kizugawa-shi (JP)

(73) Assignee: KYOCERA CORPORATION, Kyoto-shi, Kyoto (JP)

(21) Appl. No.: 13/700,077

(22) PCT Filed: Mar. 29, 2011
(86) PCT No.: PCT/JP2011/057749

§ 371 Date: Nov. 26, 2012

(30) Foreign Application Priority Data
May 27, 2010 (JP) 2010-121706

(51) Int. Cl. H03F 1/56

(52) U.S. Cl. CPC H03F 1/56
USPC 330/277

(57) ABSTRACT

Provided are an amplification circuit capable of amplifying an input signal having a changing duty ratio with high efficiency, and a transmission device and a communication device using the amplification circuit. The amplification circuit includes: a transistor circuit (10) having a pulse wave first signal having a changing duty ratio input, and a second signal obtained by amplifying the pulse wave first signal output; and a matching circuit (20) having the second signal input and a third signal having a fundamental frequency of the pulse wave first signal output. An impedance of the matching circuit (20) as seen from the transistor circuit side changes in accordance with the duty ratio of the pulse wave first signal. The transmission device and the communication device each use the amplification circuit.

### TECHNICAL FIELD

The present invention relates to a highly-efficient amplification circuit, and a transmission device and a communication device using the amplification circuit.

### BACKGROUND ART

There is known an amplification circuit in which a matching circuit is provided on an output side of a transistor circuit for amplifying an input signal (see, for example, Patent Literature

### CITATION LIST

### Patent Literature

[PTL 1] JP 63-153904 A

### SUMMARY OF INVENTION

### Technical Problem

In the conventional amplification circuit, however, the matching circuit is fixed, and hence there has been a problem in that, when an input signal having a variable duty ratio is amplified, the efficiency is lowered as the duty ratio of the input signal becomes smaller.

The present invention has been devised in view of the problem inherent in the conventional technology, and it is an object thereof to provide an amplification circuit capable of amplifying an input signal having a variable duty ratio with high efficiency, and provide a transmission device and a communication device using the amplification circuit.

### Solution to Problem

According to the present invention, there is provided a first amplification circuit, comprising: a transistor circuit having a pulse wave first signal having a variable duty ratio input, and a second signal obtained by amplifying the pulse wave first signal output; and a matching circuit having the second signal input and a third signal having a fundamental frequency of the pulse wave first signal output, wherein an impedance of the matching circuit as seen from the transistor circuit side changes in accordance with the duty ratio of the pulse wave first signal.

Further, according to a second amplification circuit of the present invention, in the first amplification circuit, the impedance of the matching circuit as seen from the transistor circuit side becomes larger as the duty ratio of the pulse wave first signal becomes smaller.

Further, according to a third amplification circuit of the present invention, in the second amplification circuit, the matching circuit comprises a variable inductor connected in series between an input and an output of the matching circuit, and the variable inductor has an inductance that becomes larger as the duty ratio of the pulse wave first signal becomes smaller.

Further, according to a fourth amplification circuit of the present invention, in the third amplification circuit, the matching circuit further comprises a variable capacitor connected between an input side of the variable inductor and a reference potential, and the variable capacitor has a capacitance that becomes smaller as the duty ratio of the pulse wave first signal becomes smaller.

Further, according to a fifth amplification circuit of the present invention, in the fourth amplification circuit, the capacitance of the variable capacitor changes logarithmically with the duty ratio of the pulse wave first signal, and the inductance of the variable inductor is inversely proportional to a square root of the duty ratio of the pulse wave first signal.

Further, according to a sixth amplification circuit of the present invention, the first amplification circuit further comprises a control circuit for changing the impedance of the matching circuit in accordance with the duty ratio of the pulse wave first signal.

Further, according to a seventh amplification circuit of the present invention, in the sixth amplification circuit, the control circuit controls the variable capacitor and the variable inductor so that the capacitance of the variable capacitor changes logarithmically with the duty ratio of the pulse wave first signal and that the inductance of the variable inductor is inversely proportional to a square root of the duty ratio of the pulse wave first signal.

Further, according to an eighth amplification circuit of the present invention, the first amplification circuit further comprises: a conversion circuit having a fourth signal having an envelope fluctuation input, and a fifth signal and a sixth signal which are constant envelope signals having a phase difference that changes in accordance with an amplitude of the fourth signal output; a first transistor including a source terminal to which the fifth signal is input and a gate terminal to which a signal in phase with the sixth signal is input; and a second transistor including a source terminal to which the sixth signal is input and a gate terminal to which a signal in phase with the fifth signal is input, and a signal output from a drain terminal of the first transistor is input to the transistor circuit as the pulse wave first signal.

According to the present invention, there is provided a transmission device, comprising a transmission circuit to which an antenna is connected via the eighth amplification circuit.

According to the present invention, there is provided a communication device, comprising a transmission circuit to which an antenna is connected via the eighth amplification circuit, and a reception circuit is connected to the antenna.

Note that, the pulse wave signal as used in the present invention includes not only an ideal square wave signal but also a signal such as a half-wave rectified signal. Further, the duty ratio of the signal is the ratio of the duration that the pulse wave signal is at High level (duration that the pulse wave signal is not 0) to the period. For example, when the signal is at High level in a half period, the duty ratio of the signal is 0.5.

### Advantageous Effects of Invention

According to the amplification circuit of the present invention, an amplification circuit capable of amplifying an input signal having a variable duty ratio with high efficiency can be obtained.

According to the transmission device of the present invention, a transmission device having low power consumption can be obtained.

According to the communication device of the present invention, a communication device having low power consumption can be obtained.

### BRIEF DESCRIPTION OF DRAWINGS

FIG. 1 A circuit diagram schematically illustrating an amplification circuit according to a first example of an embodiment of the present invention.

FIG. 2 A circuit diagram schematically illustrating an example of a control circuit in the amplification circuit illustrated in FIG. 1.

FIG. 3 A block diagram schematically illustrating an amplification circuit according to a second example of the embodiment of the present invention.

FIG. 4 A block diagram schematically illustrating a transmission device according to a third example of the embodiment of the present invention.

FIG. 5 A block diagram schematically illustrating a communication device according to a fourth example of the embodiment the present invention.

FIG. 6 A graph showing simulation results on drain efficiency of the amplification circuit according to the first example of the embodiment of the present invention illustrated in FIG. 1 and an amplification circuit according to a comparative example.

### DESCRIPTION OF EMBODIMENTS

Referring to the accompanying drawings, an amplification circuit of the present invention is described in detail below.

### First Example of Embodiment

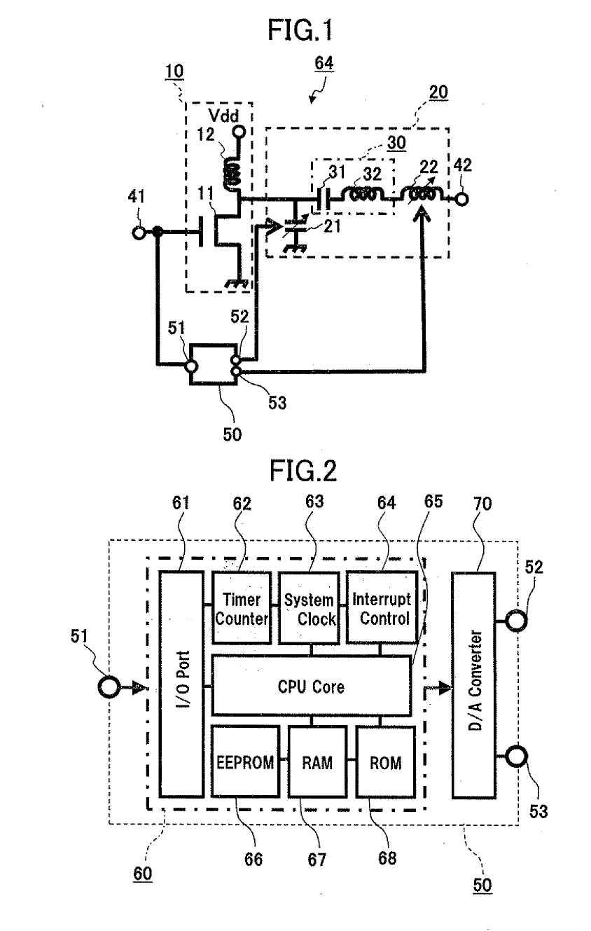

FIG. 1 is a circuit diagram illustrating an amplification circuit according to a first example of an embodiment of the present invention. FIG. 2 is a circuit diagram illustrating an example of a control circuit of FIG. 1. As illustrated in FIG. 1, the amplification circuit in this example includes a transistor circuit 10, a matching circuit 20, and a control circuit 50.

The transistor circuit 10 is connected to an input terminal 41 and the matching circuit 20. The transistor circuit 10 outputs, to the matching circuit 20, a second signal obtained by switching and amplifying a pulse wave first signal having a variable duty ratio input from the input terminal 41 in a class-B or class-AB biased state. Accordingly, the fundamental frequency of the first signal and the fundamental frequency of the second signal are equal to each other. The transistor circuit 10 includes a field-effect transistor (FET) 14 and a choke coil 12.

The FET 11 has a gate terminal connected to the input terminal 41, a drain terminal connected to the matching circuit 20 and connected to a power supply potential Vdd via the choke coil 12, and a source terminal connected to a reference potential (ground potential). The first signal input from the input terminal 41 is input to the gate terminal, and the second signal as the amplified signal is output from the drain terminal to the matching circuit 20. Although not illustrated, the gate terminal of the FET 11 is also applied with a class-B or class-AB bias via a choke inductor.

The matching circuit 20 is connected to the transistor circuit 10 and an output terminal 42. The matching circuit 20 has the second signal output from the transistor circuit 10 input, and a third signal having the fundamental frequency of the first signal and the second signal output. And, the matching circuit 20 includes a variable capacitor 21, a variable inductor 22, and an LC series resonance circuit 30.

The LC series resonance circuit 30 is connected in series between the input and output of the matching circuit 20. In other words, the LC series resonance circuit 30 is connected in series between the transistor circuit 10 and the output terminal 42. And, the LC series resonance circuit 30 resonates at the fundamental frequency of the first signal and the second signal, and has the function of allowing a signal having the fundamental frequency of the first signal and the second signal to pass with low loss and reflecting signals having other frequencies. In this way, a fundamental frequency component is extracted from the input second signal and is output as the third signal. And, the LC series resonance circuit 30 is formed of a capacitor 31 and an inductor 32 connected in series. The capacitor 31 is disposed on the input side (transistor circuit 10 side) and the inductor 32 is disposed on the output side (output terminal 42 side).

The variable inductor 22 is, similarly to the LC series resonance circuit, connected in series between the input and output of the matching circuit 20. In other words, the variable inductor 22 is connected in series between the transistor circuit 10 and the output terminal 42. More specifically, the variable inductor 22 is connected in series on the output side of the LC series resonance circuit 30, that is, between the inductor 32 of the LC series resonance circuit 30 and the output terminal 42. And, the variable inductor 22 is controlled so as to have a larger inductance as the duty ratio of the first signal becomes smaller. More specifically, the variable inductor 22 is controlled so that the inductance is inversely proportional to the square root of the first signal.

The variable capacitor 21 is connected between the input side of the variable inductor 22 and the reference potential (ground potential), and the LC series resonance circuit 30 is inserted between the variable inductor 22 and the variable capacitor 21. In other words, the variable capacitor 21 is connected between the input side (transistor circuit 10 side) of the capacitor 31 of the LC series resonance circuit 30 and the ground potential. And, the variable capacitor 21 is controlled so as to have a smaller capacitance as the duty ratio of the first signal becomes smaller. More specifically, the variable capacitor 21 is controlled so that the capacitance changes logarithmically with the duty ratio of the first signal.

The control circuit 50 has a terminal 51 connected to the input terminal 41, a terminal 52 connected to the variable capacitor 21 of the matching circuit 20, and a terminal 53 connected to the variable inductor 22 of the matching circuit 20. And, the control circuit 50 outputs a control signal for controlling the capacitance of the variable capacitor 21 in accordance with the duty ratio of the first signal to the variable capacitor 21, and outputs a control signal for controlling the inductance of the variable inductor 22 in accordance with the duty ratio of the first signal to the variable inductor 22.

As illustrated in FIG. 2, the control circuit 50 includes a RISC controller 60 connected to the terminal 51, and a DA converter 70 connected to the RISC controller 60, the terminal 52, and the terminal 53. And, the RISC controller 60 includes an I/O port 61, a timer counter 62, a system clock 63, an interrupt controller 64, a CPU core 65, an EEPROM 66, a RAM 67, and a ROM 68.

In the control circuit 50 having the above-mentioned configuration, for example, when the first signal is input from the input terminal 41, the timer counter 62 measures a time period during which the first signal is at High level. Next, a correspondence table between the duty ratio of the first signal and the period at High level, which is prestored in the ROM 68, is referred and the duty ratio of the first signal is determined. Next, a correspondence table between the duty ratio of the first signal and a control voltage applied to the variable capacitor 21, which is prestored in the ROM 68, is referred and the value of the control voltage to be applied to the variable capacitor 21 is determined. Similarly, a correspondence table between the duty ratio of the first signal and a control voltage applied to the variable inductor 22 is referred and the value of the control voltage to be applied to the variable inductor 22 is determined. Next, the value of the control voltage to be applied to the variable capacitor 21 and the value of the control voltage to be applied to the variable inductor 22 are converted into analog values in the DA converter 70, and the obtained values are output to the variable capacitor 21 and the variable inductor 22 from the terminals 52 and 53, respectively.

According to the amplification circuit having the above-mentioned configuration in this example, the variable capacitor 21 is controlled so as to have a smaller capacitance as the duty ratio of the input first signal becomes smaller, and the variable inductor 22 is controlled so as to have a larger inductance as the duty ratio of the first signal becomes smaller, and hence the transmission amount of a harmonic component can be reduced as the duty ratio of the first signal becomes smaller. In this way, the amplification circuit capable of amplifying an input signal having a variable duty ratio with high efficiency can be obtained.

The mechanism for obtaining this effect can be presumed as follows. That is, the frequency spectrum of the input first signal spreads more as the duty ratio becomes smaller, and the intensity of a frequency component at the fundamental frequency decreases. At the same time, the intensity of a harmonic component increases with respect to the frequency component at the fundamental frequency. In the case where the impedance of the matching circuit is fixed, as the duty ratio becomes smaller, the increased harmonic component is supplied to a load circuit such as an antenna via the output terminal 42 and consumed as unnecessary electric power. As described above, if the harmonic component to be transmitted to the load circuit increases, the efficiency of the amplification circuit deteriorates.

In the amplification circuit in this example, on the other hand, the impedance of the matching circuit 20 as seen from the transistor circuit 10 side changes in accordance with the duty ratio of the input first signal. Specifically, the capacitance of the variable capacitor 21 becomes smaller and the inductance of the variable inductor 22 becomes larger as the duty ratio becomes smaller, and hence the impedance of the matching circuit 20 as seen from the transistor circuit 10 side becomes larger as the duty ratio of the first signal becomes smaller. In this way, the impedance of the matching circuit 20 changes so that the harmonic component is less liable to be transmitted as the duty ratio of the first signal becomes smaller, and hence unnecessary electric power consumed by the load circuit when the duty ratio is small can be reduced. Thus, the efficiency of the amplification circuit is improved.

Further, according to the amplification circuit in this example, the variable capacitor 21 is controlled so that the capacitance changes logarithmically with the duty ratio of the first signal, and the variable inductor 22 is controlled so that the inductance is inversely proportional to the square root of the first signal, and hence an amplification circuit capable of more efficiently amplifying the input first signal having a changing duty ratio can be obtained. Various studies made by the inventors of the present invention have revealed that the efficiency of the amplification circuit can be enhanced significantly by changing the capacitance of the variable capacitor 21 and the inductance of the variable inductor 22 as described above.

As the variable inductor 22 used in the amplification circuit in this example, a conventionally known variable inductor, such as an inductor whose inductance is changed by switching connections among a plurality of lines by a switch or an inductor whose inductance is changed by moving a magnetic body disposed in proximity to a coil, can be used. As the variable capacitor used in the amplification circuit in this example, a known variable capacitor can be used.

### Second Example of Embodiment

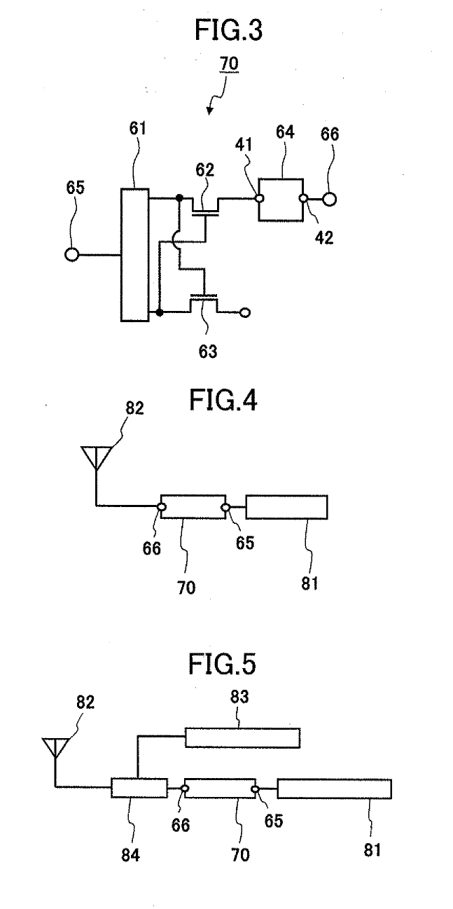

FIG. 3 is a circuit diagram illustrating an amplification circuit according to a second example of the embodiment of the present invention. As illustrated in FIG. 3, the amplification circuit in this example includes a conversion circuit 61, FETs 62 and 63, the amplification circuit 64 illustrated in FIG. 1, and terminals 65 and 66.

The conversion circuit 61 converts a fourth signal, which is a signal having an envelope fluctuation input from the terminal 65, into a fifth signal and a sixth signal, which are two constant envelope signals having the same frequency as the fourth signal and having a phase difference that changes in accordance with the amplitude of the fourth signal, and outputs the fifth signal and the sixth signal. Accordingly, the change in amplitude of the fourth signal is replaced by the change in phase difference between the fifth signal and the sixth signal. Note that, as such a conversion circuit 61, various kinds of conventionally known constant envelope signal generation circuits can be used.

The FET 62 has a source terminal to which the fifth signal is input and a gate terminal to which the sixth signal is input. The FET 63 has a source terminal to which the sixth signal is input and a gate terminal to which the fifth signal is input. The FET 63 has a drain terminal terminated by predetermined impedance (not shown). Note that, although not illustrated, the gate terminals of the FETs 62 and 63 are also applied with a class-B or class-AB bias via choke coils. Since adjustment by the biases applied to the respective gate terminals is available, the signal to be input to the gate terminal of the FET 62 may be any signal in phase with the sixth signal, and the signal to be input to the gate terminal of the FET 63 may be any signal in phase with the fifth signal.

In this way, the FETs 62 and 63 form a transfer gate circuit, and the FET 62 allows the fifth signal to pass only when the voltage of the sixth signal is higher than an ON-voltage. The pulse wave first signal output from the FET 62 is input to the gate terminal of the FET 11 of the amplification circuit 64. Accordingly, the FET 11 of the amplification circuit 64 becomes the ON state only in the period when the fifth signal and the sixth signal are both higher than the ON-voltage. The duration of the ON state changes in accordance with the phase difference between the fifth signal and the sixth signal. Thus, the change in phase difference between the fifth signal and the sixth signal is replaced by the change in pulse width of the second signal output from the FET 11.

A fundamental period during which the FET 11 is in the ON state is coincident with a fundamental period during which the fifth signal and the sixth signal are both higher than the ON-voltage, and hence the fundamental frequency of the second signal output from the drain terminal of the FET 11 is equal to the same frequency as the fifth signal and the sixth signal, that is, the same frequency as the fourth signal. Thus, the third signal, which is the signal obtained by extracting the fundamental frequency component from the second signal, becomes a signal having the same frequency as the fourth signal. Further, the amplitude of the third signal changes in accordance with the pulse width of the second signal and therefore changes in accordance with the amplitude of the fourth signal. In this way, the third signal has the same frequency as the fourth signal and the amplitude that changes in accordance with the amplitude of the fourth signal, and is therefore a signal obtained by amplifying the fourth signal.

According to the amplification circuit having the above-mentioned configuration in this example, an amplification circuit capable of efficiently amplifying an input signal having an envelope fluctuation can be obtained.

### Third Example of Embodiment

FIG. 4 is a block diagram illustrating a transmission device according to a third example of the embodiment of the present invention. As illustrated in FIG. 4, in the transmission device in this example, an antenna 82 is connected to a transmission circuit 81 via an amplification circuit 70 illustrated in FIG. 3. Note that, the terminal 65 of the amplification circuit 70 is connected to the transmission circuit 81, and the terminal 66 thereof is connected to the antenna 82. According to the transmission device having the above-mentioned configuration in this example, a transmission signal having an envelope fluctuation output from the transmission circuit 81 can be amplified with the use of the highly-efficient amplification circuit 70, and hence a transmission device having low power consumption can be obtained.

### Fourth Example of Embodiment

FIG. 5 is a block diagram illustrating a communication device according to a fourth example of the embodiment of the present invention. As illustrated in FIG. 5, in the communication device in this example, an antenna 82 is connected to a transmission circuit 81 via the amplification circuit 70 illustrated in FIG. 3, and a reception circuit 83 is connected to the antenna 82. Further, an antenna duplexer circuit 84 is inserted between the antenna 82 and the transmission circuit 81 and between the antenna 82 and the reception circuit 83. Note that, the terminal 65 of the amplification circuit 70 is connected to the transmission circuit 81, and the terminal 66 thereof is connected to the antenna 82. According to the communication device having the above-mentioned configuration in this example, a transmission signal having an envelope fluctuation output from the transmission circuit 81 can be amplified with the use of the highly-efficient amplification circuit 70, and hence a communication device having low power consumption can be obtained.

### Modified Example

The present invention is not limited to the above-mentioned examples of the embodiment, and various changes and modifications can be made thereto.

For example, although the matching circuit 20 including the variable inductor 22 and the variable capacitor 21 has been exemplified in the above-mentioned first example of the embodiment, the present invention is not limited thereto. For example, the matching circuit 20 may include only one of the variable inductor 22 and the variable capacitor 21. Alternatively, the matching circuit 20 may include a variable resistor and change the resistance value of the variable resistor to thereby change the impedance of the matching circuit 20. As the variable resistor, for example, a known variable resistor configured to switch connections among a plurality of lines or resistive elements by a switch can be used.

Further, although the communication device including the antenna duplexer circuit 84 has been exemplified in the above-mentioned fourth example of the embodiment, the present invention is not limited thereto. The communication device may not include the antenna duplexer circuit 84.

### Example

Next, a specific example of the amplification circuit of the present invention is described. Simulation was carried out to calculate drain efficiency in the amplification circuit according to the first example of the embodiment of the present invention illustrated in FIG. 1. A gallium arsenide FET was used as the FET 11, and a power source of −2.5 V was connected to its gate terminal via the choke inductor so that the FET 11 operated with a class-AB bias. Vdd was set to 4.5 V. The frequency of the input first signal was set to a rectangular wave of 1 GHz. The capacitance of the capacitor 31 was set to 10 pF, and the value of the inductor 32 was set to 1 nH. The capacitance C(x) of the variable capacitor 21 and the inductance L(x) of the variable inductor 22 were caused to change as shown in Expressions (1) and (2) below.

L(x)=12/√x (1)

C(x)=0.57*ln(x)+1.22 (2)

where x represents the duty ratio of the first signal.

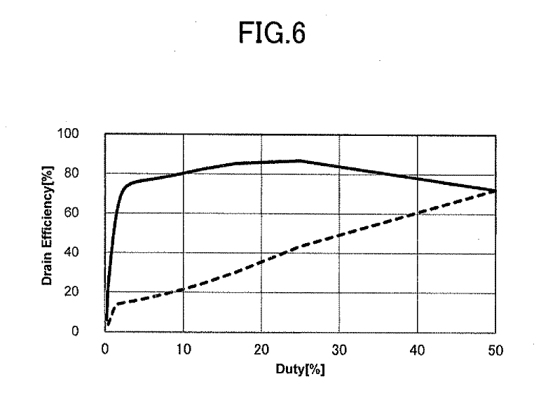

The simulation results are shown in a graph of FIG. 6. The graph of FIG. 6 also shows simulation results of an amplification circuit according to a comparative example, in which the capacitance of the variable capacitor 21 and the inductance of the variable inductor 22 were fixed to the values of C(x) and L(x) at the duty ratio of 0.5. In the graph, the horizontal axis represents the duty ratio of the first signal, and the vertical axis represents the efficiency (drain efficiency) of the amplification circuit. The solid line indicates the simulation results of the amplification circuit according to the first example of the embodiment of the present invention illustrated in FIG. 1, and the broken line indicates the simulation results of the amplification circuit according to the comparative example.

As apparent from the graph of FIG. 6, the efficiency of the amplification circuit according to the comparative example is lowered significantly along with the decrease in duty ratio of the input first signal. On the other hand, in the amplification circuit according to the first example of the embodiment of the present invention illustrated in FIG. 1, high efficiency comparable with that at the duty ratio of 50% is maintained until the duty ratio is decreased to about 3%. Thus, the effectiveness of the present invention was confirmed.

### REFERENCE SIGNS LIST

10: transistor circuit
20: matching circuit
11, 62, 63: FET
21: variable capacitor
22: variable inductor
61: conversion circuit
64, 70: amplification circuit
81: transmission circuit
82: antenna
83: reception circuit

1. An amplification circuit, comprising:
a transistor circuit having a pulse wave first signal having a variable duty ratio input and a second signal obtained by amplifying the pulse wave first signal output; and
a matching circuit having the second signal input and a third signal having a fundamental frequency of the pulse wave first signal output,
wherein an impedance of the matching circuit as seen from the transistor circuit side changes in accordance with the duty ratio of the pulse wave first signal.

2. The amplification circuit according to claim 1, wherein the impedance of the matching circuit as seen from the transistor circuit side becomes larger as the duty ratio of the pulse wave first signal becomes smaller.

3. The amplification circuit according to claim 2, wherein the matching circuit comprises a variable inductor connected in series between an input and an output of the matching circuit,
wherein the variable inductor has an inductance that becomes larger as the duty ratio of the pulse wave first signal becomes smaller.

4. The amplification circuit according to claim 3, wherein the matching circuit further comprises a variable capacitor connected between an input side of the variable inductor and a reference potential,
wherein the variable capacitor has a capacitance that becomes smaller as the duty ratio of the pulse wave first signal becomes smaller.

5. The amplification circuit according to claim 4, wherein the capacitance of the variable capacitor changes logarithmically with the duty ratio of the pulse wave first signal, and the inductance of the variable inductor is inversely proportional to a square root of the duty ratio of the pulse wave first signal.

6. The amplification circuit according to claim 1, further comprising a control circuit for changing the impedance of the matching circuit in accordance with the duty ratio of the pulse wave first signal.

7. The amplification circuit according to claim 6, wherein the control circuit controls the variable capacitor and the variable inductor so that the capacitance of the variable capacitor changes logarithmically with the duty ratio of the pulse wave first signal and that the inductance of the variable inductor is inversely proportional to a square root of the duty ratio of the pulse wave first signal.

8. The amplification circuit according to claim 1, further comprising:
a conversion circuit having a fourth signal having an envelope fluctuation input and, a fifth signal and a sixth signal which are constant envelope signals having a phase difference that changes in accordance with an amplitude of the fourth signal output;
a first transistor including a source terminal to which the fifth signal is input and a gate terminal to which a signal in phase with the sixth signal is input; and
a second transistor including a source terminal to which the sixth signal is input and a gate terminal to which a signal in phase with the fifth signal is input,
wherein a signal output from a drain terminal of the first transistor is input to the transistor circuit as the pulse wave first signal.

9. A transmission device, comprising a transmission circuit to which an antenna is connected via the amplification circuit according to claim 8.

10. A communication device, comprising a transmission circuit to which an antenna is connected via the amplification circuit according to claim 8,
wherein a reception circuit is connected to the antenna.
